(19) United States
(12) Patent Application Publication
(10) Pub. No.: US 2002/0096253 A1
(43) Pub. Date: Jul. 25, 2002

(54) Methods Of Attaching A Sheet Of An Adhesive Film To A Substrate In The Course Of Making Integrated Circuit Packages

(75) Inventors: Mr. Il Kwon Shim, Tempe, AZ (US); Mr. Do Sung Chun, Tambon Saladang Amphur Bang-num-Priew (TH); Mr. Vincent DiCaprio, Mesa, AZ (US); Mr. Paul Hoffman, Chandler, AZ (US)

Correspondence Address: James E. Parsons, Skjerven Morrill Macpherson, LLP, 25 Metro Drive #700, San Jose, CA, 95110, US, jparsons@skjerven.com, 408-453-9200

(73) Assignee: AMKOR Technology, Inc.,, Chandler, 85248-1604

(21) Appl. No.: 09/449,070

(22) Filed: Nov. 23, 1999

(51) Int. Cl. H01L 21/44

(52) U.S. Cl. 156/297; 156/299; 29/740; 438/119

(57) ABSTRACT

### Abstract

Methods of making packages for integrated circuit devices are described. An exemplary method includes providing a substrate sheet having an array of package sites at which individual integrated circuit packages will be assembled. A continuous sheet of an adhesive film is placed on the substrate strip so as to cover the plurality of package sites. The adhesive film sheet is then cured by applying heat or pressure or heat and pressure to the substrate strip and the sheet of adhesive film. The pressure and/or heat cause the sheet of adhesive film to be permanently attached to the substrate strip. A subsequent step forms one or more apertures though the joined substrate strip and adhesive film at each package site. An integrated circuit die is mounted on the adhesive film at each package site, and bond wires are attached through the aperture between metallizations of the substrate and the integrated circuit device. After the one or more apertures at each site are filled with an insulative material, the adjacent package sites are separated, forming individual packages each having an integrated circuit device.

### Background of Invention

1.Field of the Invention The present invention concerns packaging for integrated circuits, and in particular concerns a method for attaching a sheet of an adhesive film to a substrate used to manufacture a plurality of integrated circuit packages.

2.Description of Related Art Integrated circuit packages typically include an integrated circuit die attached to a substrate by an adhesive layer. Bond wires or equivalent conductors are connected between the integrated circuit die and metallizations on the substrate. The metallizations are connected to other metal structures of the substrate, such as bonding pads or solder balls, for connecting the package to a printed circuit board.

Typically, a plurality of packages are built in parallel on substrate strip. The strip may be formed, for example, of a thin insulative film such as a polyimide film or an epoxy laminate film. Alternatively, the substrate strip may be an array of interconnected metal leadframes.

Such conventional substrate strips include a plurality of package sites. A package is assembled at each package site. In particular, a die is attached to each package site of the substrate strip. Subsequently, the dies are each wire bonded to the metallizations of their respective package site. The package sites may then be encapsulated. Finally, the substrate is cut with a saw or punch to form individual packages each containing a die.

An increasingly common way to attach a die to a substrate strip is to use an adhesive film, such as a B-staged epoxy film. Another adhesive film available from the W. L. Gore Co. of Arizona is formed of a Teflon-like carrier material coated with adhesives. Such adhesive films characteristically require the application of pressure and heat for the adhesive film to cure.

FIG. 1 illustrates two sequential steps in a process of making an integrated circuit package using a substrate strip 10. FIGs. 2A and 2B show a portion of substrate strip 10 as a result of the two steps. Referring to the left side of FIG. 1 and to FIG. 2A, a substrate strip 10 is unrolled from a reel 11 and fed through an adhesive film applicator 12. Two rows of sprocket holes 13 along opposite sides of substrate strip 10 are used to index and align substrate strip 10. Substrate strip 10 may be formed of a variety of materials conventionally used to make integrated circuit packages, such as a polyimide film.

Applicator 12 sequentially applies small, double sided adhesive films 14 onto substrate strip 10 in rows using a punch-like motion. Each adhesive film 14 is sized for one package site of substrate strip 10. In particular, applicator 12 individually places each adhesive film 14 on substrate strip 10, and then applies a selected amount of pressure and heat to cure the adhesive film 14 so that the adhesive film 14 is permanently attached to substrate strip 10.

The right side of FIG. 1 and FIG. 2B illustrate a subsequent step where a punch 16 sequentially punches an aperture 17 through each adhesive film 14 and through the underlying portion of substrate strip 10. Subsequently, the apertured substrate sheet and adhesive film are rolled onto a reel 15. Later, a die is attached to each adhesive film 14, and bond wires are connected to the die through each aperture 17.

The above-described step of sequentially attaching individual adhesive films 14 to substrate strip 10 at each package site has significant drawbacks. First, the step takes a relatively large amount of time because adhesive films 14 are placed and cured one at a time. Second, the quality of the lamination of each adhesive film 14 to substrate strip 11 can vary over time depending, for example, on the state of applicator 12. Third, the size of adhesive films 14 may vary from one type of package to another. Thus, different size adhesive films 14 must be kept in inventory, and time may be expended for equipment and film changeover whenever there is a change in the type of package being made.

Accordingly, what is needed is a more reliable, reproducible, efficient and cost effective process of attaching adhesive films to a substrate strip during the assembly of integrated circuit packages.

### Summary of Invention

The present invention provides a more efficient process for attaching an adhesive film to a substrate during the making of integrated circuit device packages. In one embodiment of a method within the present invention, a substrate sheet is provided. The substrate sheet has an array of package sites at which individual integrated circuit packages will be assembled. A continuous sheet of an adhesive film is placed on the substrate strip so as to cover the plurality of package sites. The adhesive film is then cured by applying heat and/or pressure to the substrate strip and the sheet of adhesive film. The pressure and/or heat are applied by running the substrate sheet and sheet of adhesive film under a roller or between rollers. The pressure and/or heat applied by the roller(s) cause the sheet of adhesive film to be permanently attached to the substrate strip. Optionally, a subsequent step forms one or more apertures though the joined substrate strip and adhesive film at each package site.

The methods of the present invention greatly improve on prior art processes that attach a discrete adhesive film sheet to each package site of the substrate strip. In the prior art, the adhesive films are each sized for one and only one package site, and are individually placed and cured. The processes of the present invention are much faster than such processes, since a larger sheet of adhesive film is placed on the substrate. Typically, the substrate strip will have a plurality of rows and columns of package sites and, in one embodiment of the present invention, a continuous sheet of adhesive film is applied to the substrate strip so as to cover all of the rows and columns of package sites with the continuous sheet of adhesive film. Using a single large sheet of adhesive film, rather than many smaller single-package-size adhesive film sheets, provides a remarkable gain in efficiency. Moreover, inventory and labor costs are reduced because different sizes and shapes of adhesive films do not have to be used or kept in inventory. Finally, the quality of the lamination between the adhesive film and the substrate is improved. In one embodiment, this improved lamination is achieved by running the substrate strip and the adhesive film under a roller that applies pressure and/or heat uniformly across a plurality of package sites.

These and other features and attributes of the present invention will become apparent through the following discussion of particular exemplary embodiments.

### Brief Description of Drawings

FIG. 1 is a side view of an applicator 12 and a punch 16 operating on a substrate strip 10.

FIG. 2A is a plan view of a portion of substrate 10 after rows and columns of small adhesive films 14 are attached thereto.

FIG. 2B is a plan view of apertures 17 through substrate strip 10 and each adhesive film 14 on substrate strip 10.

FIG. 3 is a flow chart of a method 100 of applying an adhesive film to a substrate strip and forming apertures in the film and the strip at package sites where individual packages are to be fabricated.

FIG. 4 is a side view of a sheet 30 of an adhesive film being attached to a substrate strip 10.

FIG. 5A is a plan view of a substrate strip 10 after adhesive film sheet 30 is applied to substrate strip 10.

FIG. 5B is a plan view of apertures 17 in substrate strip 10 and adhesive film sheet 30.

FIG. 6 is a partially broken perspective view of an integrated circuit package 50.

FIG. 7 is a partially broken perspective view of an alternative integrated circuit package 70.

FIG. 8 is a flow chart of a method 150 of making integrated circuit package 70 of FIG. 7.

FIGs. 9A-9I are cross-sectional side views of stages in the assembly of integrated circuit package 70 of FIG. 7.

### Detailed Description

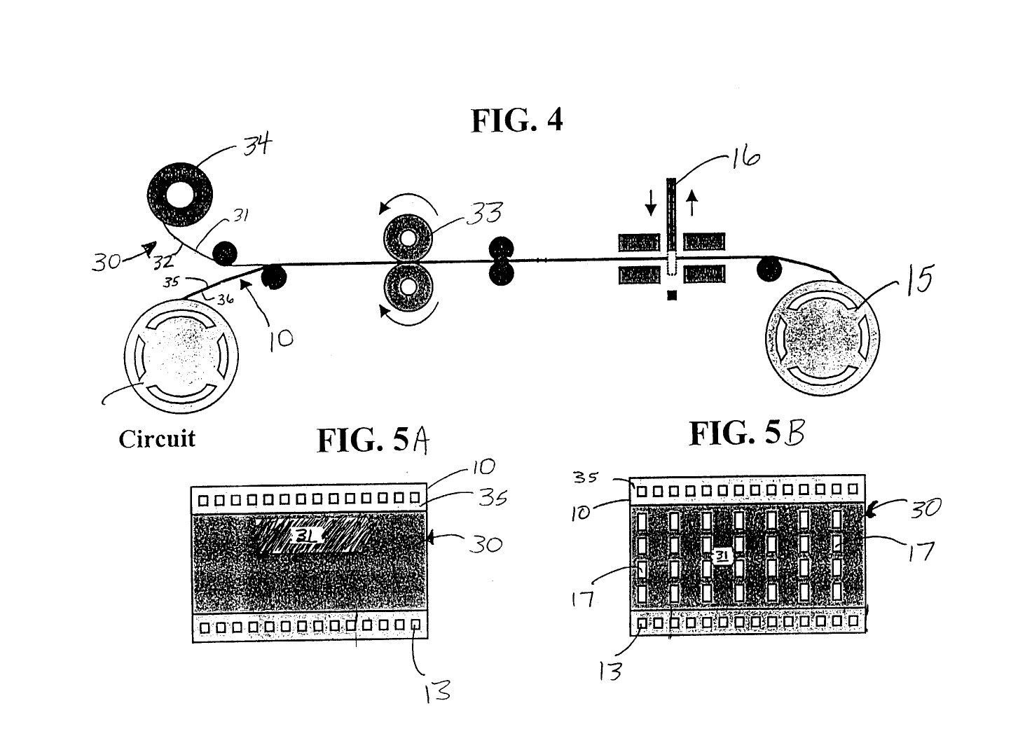

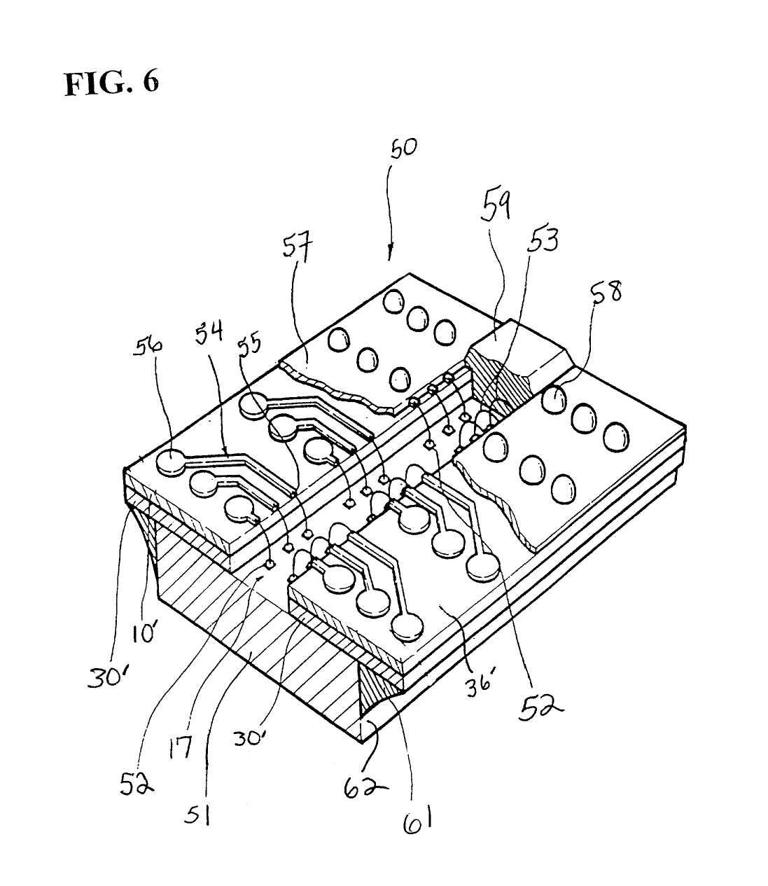

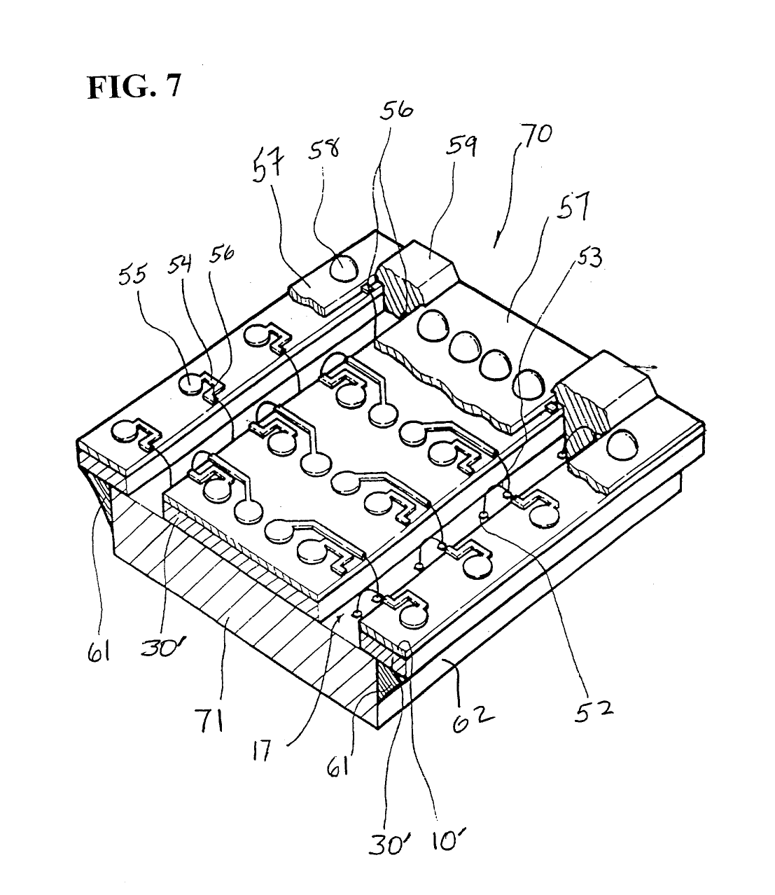

FIG. 3 is a flow chart of an embodiment of a method 100 within the present invention for applying a sheet of an adhesive film to a substrate strip and forming apertures in the joined adhesive film sheet and substrate strip at package sites where individual packages are to be fabricated. FIG. 4 is a side view of a sheet 30 of an adhesive film being attached to a substrate strip 10 and then punched with a punch 16 to form apertures 17. FIG. 5A is a plan view of a substrate strip 10 after a large, continuous adhesive film sheet 30 is attached to substrate strip 10 according to one embodiment of the present invention. FIG. 5B is a plan view of apertures 17 formed in substrate strip 10 and adhesive film sheet 30.

Step 101 of method 100 of FIG. 3 provides a sheet 30 of a double-sided adhesive film. Referring to FIGs. 4 and 5A, adhesive film sheet 30 typically will be provided on a roll 34. Adhesive film sheet 30 has a first surface 31 and an opposite second surface 32. Disposable release layers (not shown) typically will be supplied on first and second surfaces 31 and 32 of adhesive film sheet 30 to facilitate handling.

Generally speaking, adhesive film sheet 30 may be any double-sided, releasable adhesive film used in packaging applications that requires the application of pressure and/or heat for a selected amount of time to cure. Adhesive film sheet 30 may have a modulus within a range of about 8 to 15 MPa at 150 degrees C, and may be a mono-layer or multi-layer material. As an example, adhesive film sheet 30 may be a HS-202 B-staged epoxy material from the Hitachi Chemical Company of Japan, having a thickness of 25 to 200 microns.

Step 101 of method 100 of FIG. 3 also provides a substrate strip 10. Referring to FIG. 4, substrate strip 11 typically will be provided on a reel 11. Substrate strip 10 has a first surface 35, an opposite second surface 36, and a matrix of package sites where individual integrated circuit packages will be formed.

Substrate strip 10 may be formed of any conventional substrate strip material used in packaging applications. For example, substrate strip 10 may be comprised of a polymide film, a polymeric film, a BT laminate film, a PPE laminate film, an epoxy laminate film, a metal layer, or a combination of such films or layers. Substrate strip 30 also may be a patterned metal sheet that includes an array of interconnected metal leadframes.

In one embodiment, substrate strip 10 is formed of a polymide film or an epoxy laminate film, and an array of metallization patterns are provided on second surface 36 of substrate strip 10, with one such metallization pattern at each package site. The metallization patterns may be covered with an epoxy solder mask or other insulative material.

Step 102 of method 100 of FIG. 3 places adhesive film sheet 30 onto substrate strip 10 so as to cover a plurality of package sites. Referring to FIGs. 4 and 5A, Step 102 simultaneously feeds together adhesive film sheet 30 and substrate strip 10 so that second surface 32 of adhesive film sheet 30 contacts first surface 35 of substrate sheet 10 and covers all of the package sites of substrate strip 10. The release layer on second surface 32 of adhesive film sheet 30 is removed prior to the contacting of second surface 32 to first surface 35. The removal of the release layer may be done with a roller or some other conventional method. The surfaces of adhesive film sheet 30 may be slightly tacky, which would help adhesive film sheet 30 to stay in place on substrate strip 10.

Step 103 of method 100 of FIG. 3 cures adhesive film sheet 30 so that second surface 32 of adhesive film sheet 30 is permanently attached to first surface 35 of substrate strip 10. Referring to FIG. 4, Step 103 is performed by feeding the superimposed adhesive film sheet 30 and substrate strip 10 between two rollers 33. Rollers 33 apply pressure and/or heat to adhesive film sheet 30 and substrate strip 10 for an amount of time determined by the selected speed of rollers 33. Adhesive film sheet 30 is cured as a result of the application of pressure and/or heat and is thereby permanently attached to first surface 35 of substrate strip 10. The amounts of pressure, heat, and time needed to cure adhesive film sheet 30 are variable depending, for example, on the materials used and the dimensions of adhesive film sheet 30 and substrate strip 10. As an example, a sheet of HS-202 B-staged epoxy material from the Hitachi Chemical Company of Japan, having a thickness of 25 to 200 microns, may be attached to a polymide substrate strip by applying a pressure of about 0.5 to 5 kg/cm² and a temperature of about 40 to 80 degrees Celsius for about 0.1 to 0.8 seconds.

Optional step 104 of method 100 of FIG. 3 forms one or more apertures through the joined adhesive film sheet 30 and substrate strip 10 at each package site. Whether Step 104 is performed depends on the application. Referring to FIGs. 4 and 5A, Step 104 is performed using a punch 16 that punches an array of apertures 17 through the joined adhesive film sheet 30 and substrate strip 10. Apertures 17 may be formed one at a time, or a plurality of apertures 17 (e.g., a row of apertures 17) may be formed in each motion of a multi-head punch. After Step 104, the joined and apertured adhesive film sheet 30 and substrate strip 10 are rolled onto reel 15.

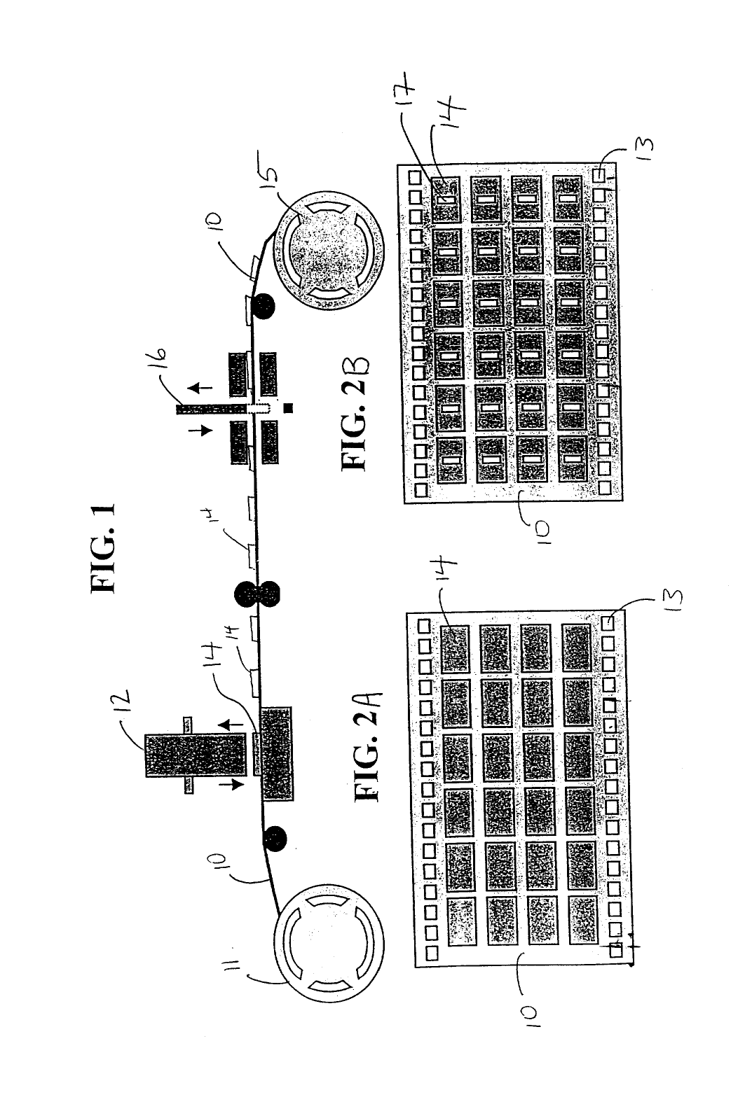

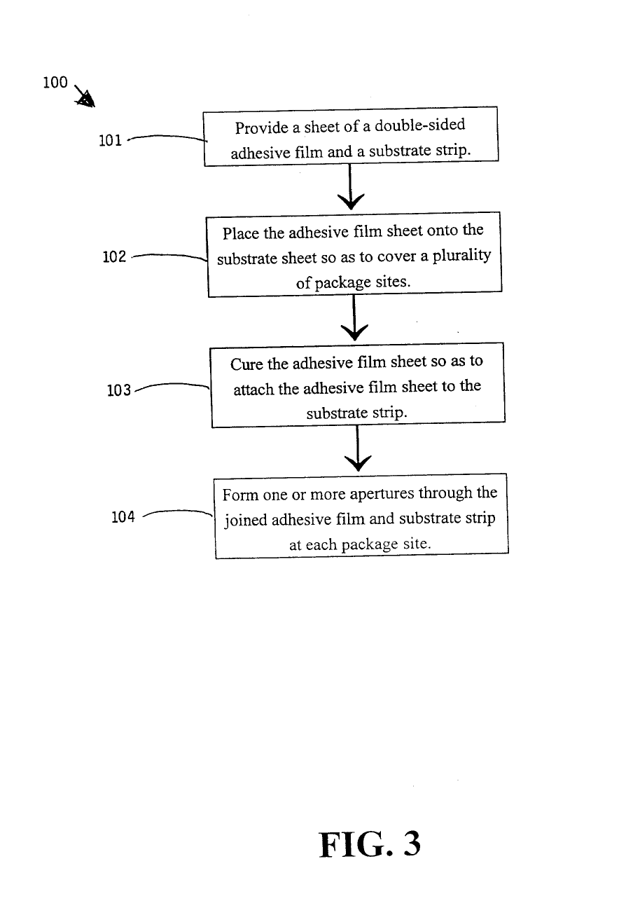

The adhesive film attachment method 100 of FIG 3, as exemplified in FIGs. 4 and 5A, provides numerous advantages over the previously-described conventional, one-at-a-time method of attaching discrete single-package-size adhesive films 14 to a substrate strip 10, as exemplified in FIGs. 1 and 2A. The advantages include much higher throughput, and more consistent and higher quality lamination. Another advantage is lower material and manpower costs, since individual adhesive films 14 (FIG. 2A) do not have to be cut from a sheet, and different sizes of individual films 14 do not have to be used or kept in inventory. Equipment costs are also lower because of the simplicity of rollers 33 (FIG. 4) compared to applicator 12 (FIG. 1).

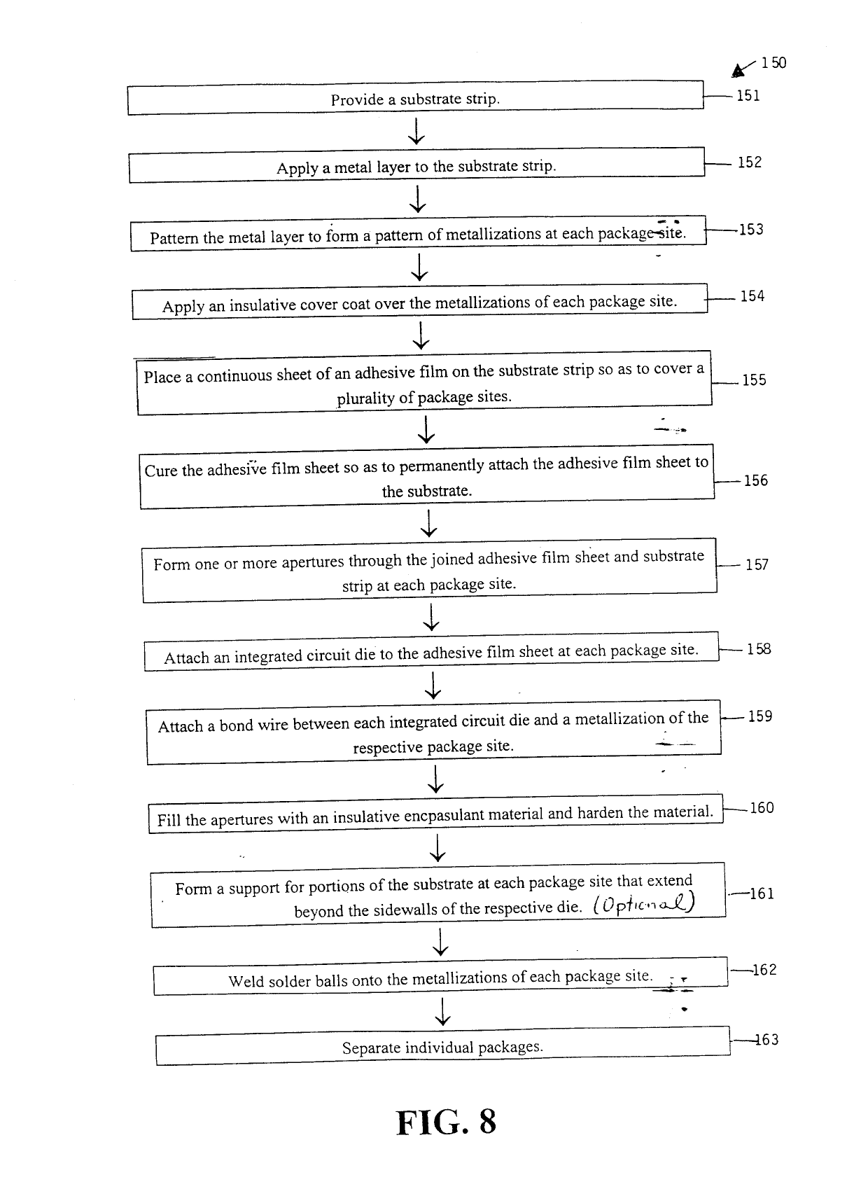

Method 100 of FIG. 3 may be used in the making of a variety of different styles of integrated circuit packages. For example, FIG. 6 shows a integrated circuit package 50 that may be made using method 100. Package 50 includes a substrate 10' formed of, for example, a polymide film or an epoxy laminate material. Integrated circuit die 51 is attached to substrate 10' by an adhesive layer 30' applied by method 100 of FIG. 3. Adhesive layer 30' extends over the entire area of substrate 10'. Adhesive layer 30' also is attached to die 51. Bond pads 52 of die 50 face a superimposed aperture 17 that is centrally located in substrate 10'. A bond wire 53 connects each bond pad 52 to a first end 55 of a metallization 54 on substrate 10'. A solder ball land 56 at an opposite second end of each metallization 54 is connected to a solder ball 58. An insulative cover coat 57 covers metallizations 54, except at their respective points of connection to bond wires 53 and solder balls 58. An insulative plug 59 of a resinous material fills aperture 17 and covers bond pads 52, bond wires 53, and first ends 55 of metallizations 54. Finally, a support 61 is formed between each of two parallel peripheral sides 62 of die 51 and the portion of adhesive film layer 30' and substrate 10' that extends beyond the respective adjacent side 62 of die 51.

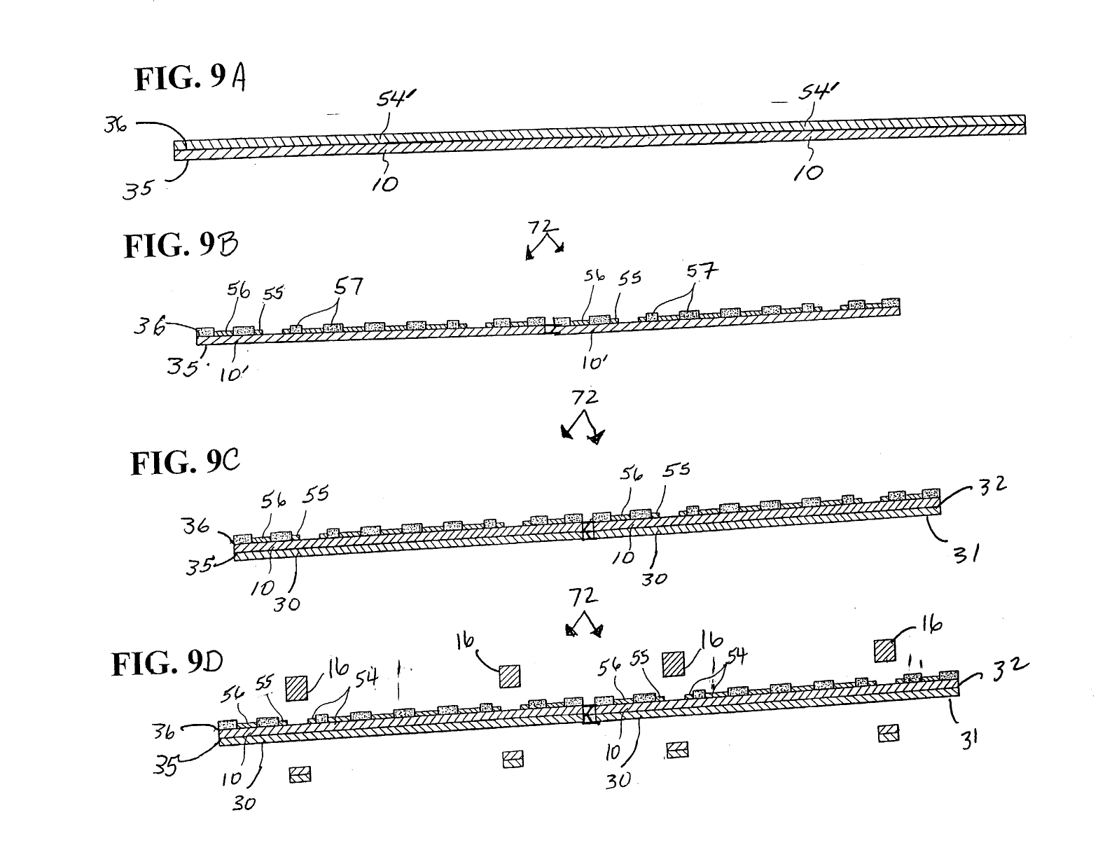

FIG. 7 shows a second integrated circuit package 70 that may be made using method 100 of FIG. 3. Package 70 has many features in common with package 50 of FIG. 6, and therefore redundant discussion is omitted. A difference between package 70 of FIG. 7 and package 50 of FIG. 6 is that integrated circuit die 71 of FIG. 7 has two rows of bond pads 52. Each row of bond pads 52 is located proximate to one of the peripheral sides 62 of die 71. Accordingly, package 70 has two apertures 17 each superimposed with one of the rows of bond pads 52, two sets of bond wires 53, and two plugs 59.

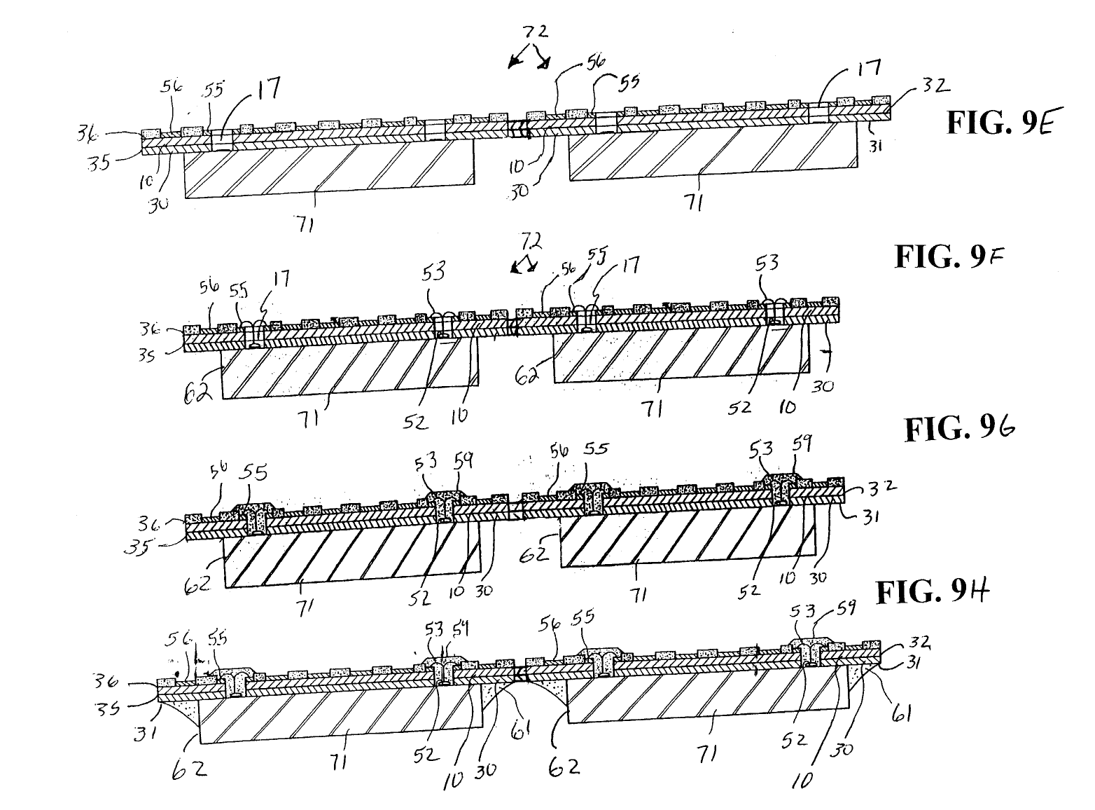

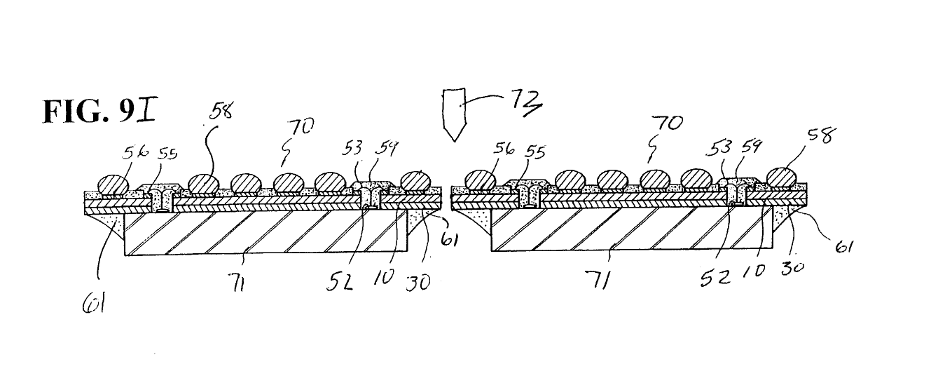

FIG. 8 is a flow chart of an exemplary method 150 within the present invention of making integrated circuit package 70 of FIG. 7. FIGs. 9A-9I are cross-sectional side views of the assembly of package 70 according to method 150. Artisans will appreciate that package 50 of FIG. 6 may be assembled by a substantially similar method. Accordingly, a redundant discussion is omitted.

Referring to FIGs. 7, 8, and 9A-9I, Step 151 of method 150 provides a substrate strip 10 formed, for example, of a polymide film. A portion of substrate strip 10 is shown in FIG. 9A. A plurality of package sites 72 will be formed on substrate strip 10. In Step 152 of method 150, a metal layer 54' is applied to second surface 36 of substrate strip 10 by sputtering or mechanical adhesion (FIG. 9A).

Step 153 of method 150 patterns metal layer 54' by chemical etching to form a pattern of metallizations 54 at each package site of substrate strip 10 (FIGs. 7 and 9B). FIGs. 9B-9I show two package sites 72 of substrate strip 10.

Step 154 applies an insulative cover coat 55 (e.g., an epoxy solder mask material) over the metallization patterns (FIG. 9B). First ends 55 and solder ball lands 56 of metallizations 54 remain exposed for subsequent connections.

Step 155 places a relatively large, continuous, double-sided, releasable adhesive film sheet 30 onto substrate strip 10 so that second surface 32 of adhesive film sheet 30 is attached to first surface 35 of substrate strip 10 (FIG. 9C). This is performed using Step 102 of method 100 of FIG. 3, as described above. The adhesive film sheet 30 is sized so as to cover a plurality of rows and columns of package sites 72 on substrate strip 10. The adhesive film sheet continuously covers the entire area of each of the package sites 72 and any areas between package sites 72.

Step 156 of method 150 cures adhesive film sheet 30 according to Step 103 of method 100 of FIG. 3 so as to permanently attach adhesive film sheet 30 to substrate strip 10 over a plurality of package sites 72. The curing is done by applying pressure and heat for a selected amount of time.

Step 157 forms apertures 17 in joined substrate strip 10 and adhesive film sheet 30 according to Step 104 of method 100. Two apertures 17 are formed at each package site 72 (FIGs. 9D and 9E).

Step 158 attaches an integrated circuit die 71 to first surface 31 of adhesive film sheet 30 at each package site 72 of substrate strip 10. Die 71 is placed so that each of the two sets of bond pads 52 of die 70 are facing and superimposed with an aperture 17. If desired, the die attachment step may be performed in accordance with the method set forth in co-pending US patent application no. 09/412,889 (Attorney Docket No. M-7899 US), filed on October 5, 1999, which application is incorporated herein by reference. The dies 71 may be inspected prior to attachment.

Step 159 attaches bond wires 53 between bond pads 52 of each integrated circuit die 71 and first ends 55 of metallizations 54 of the respective package site 72 through an aperture 17 (FIG. 9F). Conventional bond wire techniques are used.

Step 160 fills apertures 17 with an insulative encapsulant material 59 so as to cover pads 52, bond wires 53, and the connection between bond wires 53 and first end 55 of metallizations 54 (FIG. 9G). Encapsulant 59 may be formed of a liquid encapsulant material or may be molded by transfer or injection molding techniques. The encapsulated material is then hardened by conventional methods.

Optional step 161 forms supports 61 on first surface 31 of adhesive film sheet 30 (FIG. 9H). In particular, each support 61 is formed between first surface 31 and an adjacent side 62 of die 71. A liquid encapsulant material may be used to form supports 61. In a completed package, each support 61 supports the portion of substrate 10' and adhesive film sheet 30' that extends beyond the respective adjacent side 62 of die 71.

Step 162 forms metal solder balls onto an exposed solder ball land 56 of each metallization 54 through an opening in cover coat 57 (FIG. 9I) at each package site 72. Conventional techniques and materials are used. Finally, Step 162 singulates individual packages 70 by cutting through substrate 10, adhesive film sheet 30, and support 61 between adjacent package sites 72 (FIG. 9I). A saw 73 is used.

The present invention also can be used to create a variety of other packages. For example, with modifications, some or all of the packages shown in co-pending U.S. patent applications 09/422,027 (attorney docket no. AB-884 US), ___________ (attorney docket no. AB-885 US), and 09/422,115 (attorney docket no. AB-886 US), all of which were filed on October 20, 1999, can be assembled using the present invention. These applications are incorporated herein by reference.

The embodiments described herein are merely examples of the present invention. Artisans will appreciate that variations are possible within the scope of the claims.

Claims

1.A method of applying a sheet of an adhesive film to a substrate while making integrated circuit device packages, the method comprising:
providing a substrate having a plurality of package sites, wherein an integrated circuit device is to be placed on each package site;
placing a continuous sheet of an adhesive film on the substrate so as to cover the plurality of package sites; and
curing the sheet of adhesive film so that the adhesive film sheet is attached to the substrate over the plurality of package sites.

2.The method of claim 1, wherein the sheet of adhesive film is cured by applying heat or pressure or heat and pressure to the substrate and sheet of adhesive film.

3.The method of claim 3, wherein the heat or pressure or heat and pressure are applied by running the substrate and sheet of adhesive film beneath a roller.

4.The method of claim 3, wherein said substrate is unrolled from a first reel and the sheet of adhesive film is unrolled from a second reel prior to the placement of the sheet of adhesive film on the substrate.

5.The method of claim 4, wherein after curing the joined substrate strip and sheet of adhesive film are rolled onto a reel.

6.The method of claim 5, further comprising forming one or more apertures through the joined substrate and sheet of adhesive film at each package site after curing.

7.The method of claim 6, wherein the substrate includes a plurality of rows and columns of package sites, and the adhesive film is sized so as to cover said plurality of rows and columns of package sites.

8.The method of claim 2, wherein the substrate includes a plurality of rows and columns of package sites, and the adhesive film is sized so as to cover said plurality of rows and columns of package sites.

9.The method of claim 8, wherein the heat or pressure or heat and pressure are applied by running the substrate and sheet of adhesive film beneath a roller.

10.The method of claim 8, wherein said substrate is unrolled from a first reel and the sheet of adhesive film is unrolled from a second reel prior to the placement of the sheet of adhesive film on the substrate, and after curing the joined substrate and sheet of adhesive film are rolled onto a reel.

11.The method of claim 8, further comprising forming one or more apertures through the joined substrate and sheet of adhesive film at each package site after curing.

12.A method of making a plurality of integrated circuit packages, wherein each package contains an integrated circuit die, said method comprising:
providing a substrate having a plurality of package sites, wherein an integrated circuit device is to be placed at each package site, and each package site includes first conductors;
placing a continuous sheet of an adhesive film on the substrate so as to cover the plurality of package sites;
curing the sheet of adhesive film so that the adhesive film sheet is attached to the substrate over the plurality of package sites;
placing an integrated circuit device on the adhesive film sheet at each package site;
electrically connecting each integrated circuit device to the first conductors of the respective package site; and
singulating individual packages from the substrate.

13.The method of claim 12, wherein the sheet of adhesive film is cured by applying heat or pressure or heat and pressure to the substrate and sheet of adhesive film.

14.The method of claim 13, wherein the heat or pressure or heat and pressure are applied by running the substrate and sheet of adhesive film beneath a roller.

15.The method of claim 14, wherein said substrate is unrolled from a first reel, the sheet of adhesive film is unrolled from a second reel, and after curing the joined substrate and sheet of adhesive film are rolled onto a reel.

16.The method of claim 13, further comprising forming one or more apertures through the joined substrate and sheet of adhesive film at each package site after curing.

17.The method of claim 16, wherein the substrate includes a plurality of rows and columns of package sites, and the adhesive film is sized so as to cover said plurality of rows and columns of package sites.

18.The method of claim 12, wherein the substrate includes a plurality of rows and columns of package sites, and the adhesive film is sized so as to cover said plurality of rows and columns of package sites.

19.The method of claim 12, wherein the sheet of adhesive film is cured by applying heat or pressure or heat and pressure to the substrate and sheet of adhesive film and/or over a plurality of package sites.

20.The method of claim 19, wherein the heat or pressure or heat and pressure are applied by running the substrate and sheet of adhesive film beneath a roller.

21.The method of claim 19, wherein said substrate is unrolled from a first reel, the sheet of adhesive film is unrolled from a second reel, and after curing the joined substrate and sheet of adhesive film are rolled onto a reel.

22.The method of claim 12, further comprising forming one or more apertures through the joined substrate and sheet of adhesive film at each package site after curing;
filling the one or more apertures of each package site with an insulative material; and
electrically connecting solder balls to the first conductors of each package site.

23.The method of claim 22, wherein the sheet of adhesive film is cured by applying heat or pressure or heat and pressure to the substrate and sheet of adhesive film.
